(19) United States
(12) Patent Application Publication
(10) Pub. No.: US 2016/0336495 A1
(43) Pub. Date: Nov. 17, 2016

(54) OPTOELECTRONIC SEMICONDUCTOR COMPONENT AND METHOD FOR PRODUCING AN OPTOELECTRONIC SEMICONDUCTOR COMPONENT

(71) Applicant: OSRAM OPTO SEMICONDUCTORS GMBH, Regensburg, DE (US)

(72) Inventors: Thomas SCHWARZ, Regensburg (DE); Frank SINGER, Regenstauf (DE)

(21) Appl. No.: 15/106,218

(22) PCT Filed: Dec. 17, 2014
(86) PCT No.: PCT/EP2014/078272

§ 371 Date: Jun. 17, 2016

(30) Foreign Application Priority Data
Dec. 18, 2013 (DE) 10 2013 114 345.8

(51) Int. Cl. H01L 33/60; H01L 33/00

(52) U.S. Cl. CPC H01L 33/60; H01L 33/0095; H01L 2933/0058

(57) ABSTRACT

The invention relates to an optoelectronic semiconductor component comprising an optoelectronic semiconductor chip. In particular, the optoelectronic semiconductor component is a radiation-emitting semiconductor component which is designed as a side emitter. The invention also relates to a method for producing an optoelectronic semiconductor component of said type.

An optoelectronic semiconductor component with an optoelectronic semiconductor chip is provided. In particular, the optoelectronic semiconductor chip is a radiation-emitting semiconductor component, which is configured as a side emitter.

Side emitters are used as background lighting for displays, for example, wherein the radiation emitted by a side emitter is laterally coupled in a light conductor. As increasingly flat displays with increasingly thin light conductors are desired, side emitters with a low installation height are needed. However, the reduction in components entails a diminution in component parts, such as reflectors, for example. However, the resulting diminished reflectivity leads to a reduction in the radiation coupled in the light conductor, i.e. the radiation performance is reduced in a preferred direction.

It is an object of the present application is to provide an optoelectronic semiconductor component with a low installation height and undiminished radiation performance in a preferred direction. It is another object to provide a method for producing an optoelectronic semiconductor component with a low installation height and undiminished radiation performance in a preferred direction.

According to at least one embodiment, the optoelectronic semiconductor component comprises an optoelectronic semiconductor chip. Said optoelectronic semiconductor chip is in particular a radiation-emitting semiconductor chip. The optoelectronic semiconductor chip preferably comprises a semiconductor layering sequence, having an active zone for generating electromagnetic radiation, preferably in the visible area of the optic spectrum. Said semiconductor layering sequence can be grown on a growth substrate by means of an epitaxial process, for example by means of metal-organic vapour-phase epitaxy (MOVPE) or molecular beam epitaxy (MBE). The semiconductor layering sequence or at least one layer thereof can be formed of a nitride IIIN compound semiconductor material, preferably AlnGamInl-n-mN, wherein 0≦n≦1, 0≦m≦1 and n+m≦1. This material need not necessarily be a mathematically exact composition according to the above formula. Rather, it can have one or a plurality of dopants as well as additional ingredients, which do not essentially change the characteristic physical properties of the AlnGamInl-n-mN material. For the sake of simplicity, however, the above formula contains only the essential components of the crystal lattice (Al, Ga, In, N), even though the latter can be partially replaced by small amounts of further substances.

For example, the semiconductor chip concerned can be a thin-film semiconductor chip. This means, in particular, that the growth substrate is severely thinned or completely removed from the semiconductor layering sequence after the growth of said semiconductor layering sequence. The semiconductor layering sequence can be arranged on a surrogate substrate.

In particular, the semiconductor chip is a surface emitter.

Furthermore, the semiconductor chip can be a volume emitter, which preferably emits radiation of substantially the same intensity in a plurality of directions in space.

The semiconductor chip concerned can also be a flip-chip having a radiation-penetrable substrate, through which at least part of the generated radiation is coupled out of the semiconductor chip.

For example, a sapphire substrate can be used as growth substrate.

According to at least one embodiment, the optoelectronic semiconductor component comprises a carrier element. Said carrier element has in particular a first main surface, a second main surface opposite to the first main surface and multiple side surfaces, which connect the first and second main surface. The optoelectronic semiconductor chip is preferably arranged on the side of the first main surface on the carrier element. For example, the carrier element can be an even carrier, limited by even surfaces. However, it is also conceivable that the carrier element is configured in an uneven manner and is limited by at least one uneven surface. For example, the carrier element can have a recess on the side of the first main surface in which the semiconductor chip is arranged. The first main surface is thereby configured in an uneven manner.

According to at least one embodiment, the optoelectronic semiconductor component has an assembly surface, which is provided for assembling the optoelectronic semiconductor component. The assembly surface is preferably arranged parallel to a side surface of the carrier element. In particular, the assembly surface is formed by a side surface of the carrier element. Alternatively, the assembly surface can, in particular, be arranged parallel to the second main surface of the carrier element or be formed by the second main surface of the carrier element.

According to at least one embodiment, the optoelectronic semiconductor component comprises a reflector body. Said reflector body is preferably arranged on the carrier element. The reflector body is particularly preferably arranged on the first main surface of the carrier element. In a further preferred embodiment, the reflector body is inseparably connected with the carrier element with no additional fixing means. “Inseparably” in this instance and in the following may mean that the connection between the reflector body and the carrier element can only be released by mechanical destruction or damage to the reflector body and/or carrier element.

The reflector body also preferably has a cavity in which the optoelectronic semiconductor chip is arranged. In addition, the reflector body preferably has a reflector element, which limits the cavity and consists of a metal, a metal compound or a metal sequence. Such a reflector element having metallic properties is featured by a relatively high reflectivity.

In a preferred configuration of the optoelectronic semiconductor component, the reflector body consists of a reflector element. In other words, the reflector body has no further components apart from the reflector element. Here, the reflector element is configured as a self-supporting element. “Self-supporting” in this instance and in the following may mean that no further mechanically-stabilizing element is needed to ensure a mechanical stability of the reflector element. In particular, the reflector element is galvanically grown. Said reflector element can have a height of between 20 μm and 200 μm. Furthermore, the reflector element can be realized with a wall thickness of between 10 μm and 100 μm, in particular between 30 μm and 50 μm. The low wall thickness allows a low component height of the optoelectronic semiconductor component, thus allowing component heights of between 0.15 mm and 0.4 mm to be realized.

In a further configuration of the optoelectronic semiconductor component, the reflector body comprises a reflector base body on which the reflector element is attached. In particular, the reflector base body contains a dielectric material. For example, said reflector base body can be formed of an organic material, such as a plastic. It is conceivable that the reflector base body could be designed by means of a moulding process, such as injection moulding or injection pressing directly on the carrier element, and then moulded onto the latter. This has the advantage that no fixing means is needed. Furthermore, it is conceivable that the reflector base body could be produced as one-piece or separately and as a composite, by means of a moulding process for example, and moulded on the carrier element. A photo-structurable dielectric is also a possibility for producing the reflector base body. High aspect ratios can be achieved by means of a moulding process, which is in particular implemented by a LIGA (German acronym for lithography, galvanic processes and moulding) process, or a photo-structuring. The reflector element can be produced by a metallic coating of the reflector base body. For example, the coating can be generated by means of electroless galvanic processes or by isotropic sputtering. The reflector body in this embodiment can also have a height of between 20 μm and 200 μm and be designed with a wall thickness of between 10 μm and 100 μm, in particular between 30 μm and 50 μm, thus allowing an optoelectronic semiconductor component with a low component height of between 0.15 mm and 0.4 mm to be realized.

According to a preferred configuration, the reflector element contains a base material. In particular, nickel and/or copper are used as base material. The reflector element can in particular also contain even more materials for improving the reflectivity. One layer of the reflector element adjacent to the cavity preferably consists of a highly reflective material, such as aluminium, silver or gold, for example. In this case, the reflector element is composed of a metal sequence, consisting of NiAl, CuNiAl, NiAg, CuNiAg, NiAu or CuNiAu, for example.

According to at least one embodiment, the optoelectronic semiconductor component has an enclosure, which is arranged on an external surface of the reflector body. In particular, the reflector body is laterally limited outside the cavity by the external surface. The enclosure preferably contains an electrically insulating material. A suitable electrically insulating material is plastic, for example. In particular, the enclosure on the external surface is provided for avoiding short circuits, which can occur via the reflector body when soldering, for example.

According to a preferred embodiment, the enclosure is also arranged in the cavity and covers the optoelectronic semiconductor chip. In particular, the enclosure can contain a radiation-permeable material and converter particles. The enclosure can therefore form a conversion element that is provided for converting at least one part of the radiation emitted from the semiconductor chip into radiation of a different wavelength. The enclosure on the external surface and the enclosure in the cavity can be produced advantageously in a single step.

The enclosure can, for example, be produced by means of contactless dosage (German: “Jetten”), needle dosage, deep drawing or so-called spray-coating (German: “B esprithen”).

According to at least one embodiment, the optoelectronic semiconductor component has a first contact layer and a second contact layer, which are provided for electrically connecting the optoelectronic semiconductor chip. The first and second contact layers are preferably arranged on the carrier element. In particular, the first contact layer and the second layer in each case extend from the first main surface via a side surface to the second main surface of the carrier element. The optoelectronic semiconductor chip can have a first and a second electric contact, which is provided for electrically connecting the semiconductor chip, wherein the first electric contact is connected with the first contact layer and the second electric contact is connected with the second contact layer. The contacts can be connected indirectly with the contact layers, i.e. a further fixing means, such as an electric conductor, can be arranged between contact and contact layer. Furthermore, the contacts can also be connected with the contact layers directly, i.e. with no further connecting means, and therefore contact and contact layer are in direct contact.

In a preferred configuration, the contact layers extend to the assembly surface.

According to at least one embodiment of the optoelectronic semiconductor component, the reflector body is electrically insulated from at least one of the two contact layers. For example, an insulating layer can be arranged between the reflecting body and the first and second contact layer, said insulating layer containing a dielectric material and thus ensuring an electrical insulation. Suitable materials for the insulating layer are polymers, such as polyimide, epoxide, acrylate or silicon, for example. Due to the radiation exposure, it is advantageous to configure the insulating layer in a thin manner, i.e. in particular with a thickness of a maximum of 10 μm, or to add reflecting particles thereto, of titanium dioxide for example, or to use a radiation-stable material, such as silicon, for example.

Furthermore, the carrier element onto which the contact layers and the reflector body are arranged can contain a passivated or dielectric material and thus ensure an electrical insulation.

According to at least one embodiment, the carrier element comprises a silicon substrate or a ceramic substrate. In particular, the silicon substrate is passivated on the surface and is thus not or is at least poorly electrically conductive. Substrates of silicon or ceramic are advantageously suitable for manufacturing techniques, such as photo techniques which allow small structural sizes to be achieved.

In an advantageous configuration, a first and a second through connection are arranged in the carrier element. The through connections can have a circular cross-section with an advantageously small diameter of 100 μm, which can be achieved by using photo techniques, for example. In particular, the through connections each extend from the first main surface to the second main surface of the carrier element. Furthermore, the first through connection is preferably electrically connected with the first contact layer and the second through connection with the second contact layer. The optoelectronic semiconductor component can also have a first and second connecting surface, which is arranged on the first main surface of the carrier element. In particular, the first through connection is electrically connected with the first connecting surface and the second through connection is electrically connected with the second connecting surface. For example, the optoelectronic semiconductor chip can be attached on one of the two connecting surfaces and electrically connected with the other connecting surface by an electrical conductor, for example. The connecting surfaces are preferably arranged in the cavity of the reflector body. Furthermore, the contact layers in this embodiment are in particular arranged outside the cavity of the reflector body.

Alternatively, the contact layers can extend into the cavity, thus allowing the semiconductor chip to be directly connected with the contact layers.

According to at least one embodiment, the carrier element comprises a plastic carrier. Suitable materials for said plastic carrier are FR4, epoxy or polyimide, for example. Such a carrier element is a cost-effective alternative to a silicon or ceramic substrate.

According to an alternative embodiment, the carrier element is a shaped body in which the optoelectronic semiconductor chip is partially embedded. The shaped body can be formed of a moulding composition, which contains a plastic material, for example a duroplastic material, such as epoxy or silicon. The moulding material can cover at least two side surfaces and at least partially cover a rear surface of the semiconductor chip facing the carrier element.

In addition, the plastic-containing carrier element can contain at least one filling material for improving the material properties, such as reflectivity, thermal expansion coefficient, heat conduction and elasticity. Possible filling materials are titanium dioxide, amorphous silicon dioxide, boron nitride or aluminium oxide, for example.

According to at least one embodiment of a method for producing an optoelectronic semiconductor component as described above, the following steps are performed:

providing a carrier element,

providing a reflector base body on the carrier element,

producing a reflector element composed of metal or of a metal compound in such a way that the reflector element is in direct contact with the reflector base body.

In a preferred configuration, a photo-structurable material is attached on the carrier element and then subsequently structured in such a way as to form a reflector base body with a cavity. The reflector element in direct contact with the reflector base body is generated inside the cavity.

According to at least one embodiment, the reflector element is galvanically grown. The galvanisation can be implemented with or without current flow. The reflector element is preferably grown on the carrier element. Advantageously, no additional fixing means is needed to fix the reflector element. It is as well possible that the reflector element may in particular also be inseparably connected to the carrier element with no additional fixing means. Furthermore, the reflector element can be generated by isotropic sputtering.

In an advantageous configuration, the reflector base body is removed from the carrier element after the production of the reflector element, and therefore a reflector body consisting only of the reflector element is produced.

Alternatively, the reflector base body can remain in the finished semiconductor component, such that the finished reflector body comprises a reflector base body and a reflector element. In particular, the reflector element is also arranged on external surfaces of the reflector base body here.

In a preferred configuration of the method, a carrier element composite is used for producing a plurality of semiconductor components. In areas in which carrier elements with contact layers are intended to be designed the carrier element composite preferably has elongated slots that are metallized. The carrier element composite is separated along such slots during individualisation. The separate carrier elements produced in this way each have two contact layers, which extend from the first main surface via a side surface to the second main surface.

Further advantages, advantageous embodiments and further developments result from the exemplary embodiments described in the following in conjunction with the figures.

The figures show in:

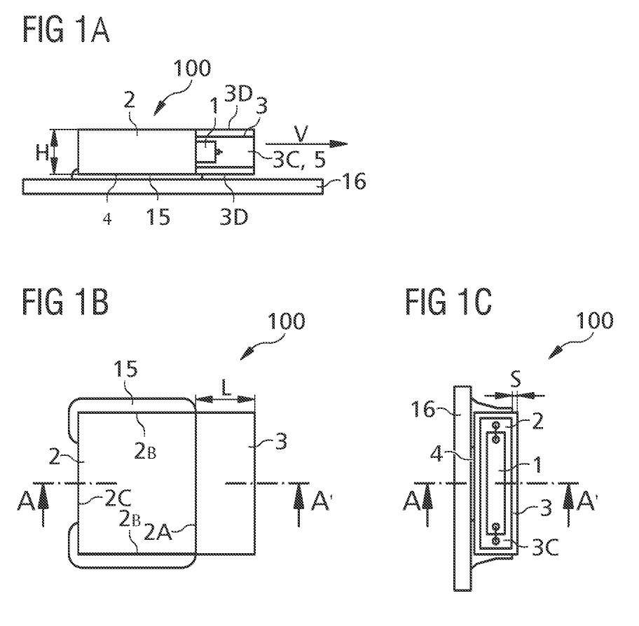

FIG. 1A, 1B, 1C the basic construction of an optoelectronic semiconductor component described herein in a top view on a connection carrier (see. FIG. 1B for comparison), in a schematic side view along the line AA′ (see FIG. 1A and 1B for comparison) and in a schematic side view perpendicular to line AA′ (see FIG. 1B and 1C for comparison),

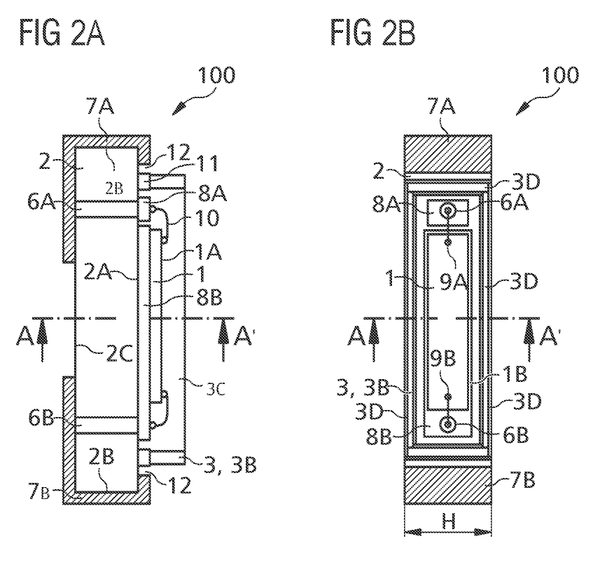

FIG. 2A and 2B a first exemplary embodiment of an optoelectronic semiconductor component in a schematic top view (FIG. 2A) and side view (FIG. 2B),

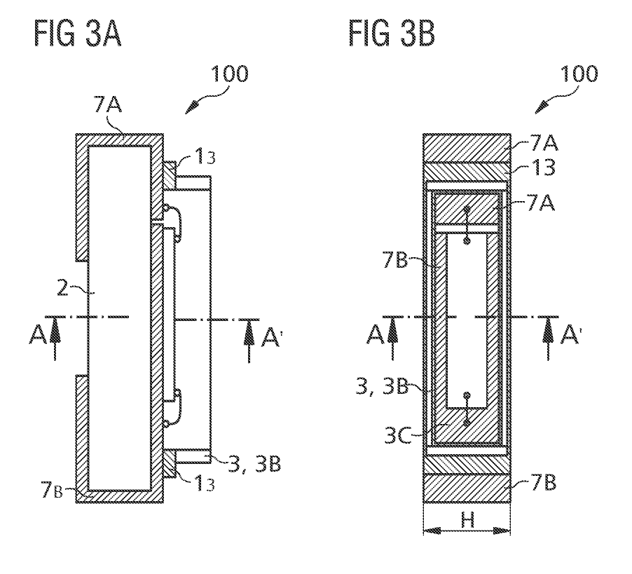

FIG. 3A and 3B a second exemplary embodiment of an optoelectronic semiconductor component in a schematic top view (FIG. 3A) and side view (FIG. 3B),

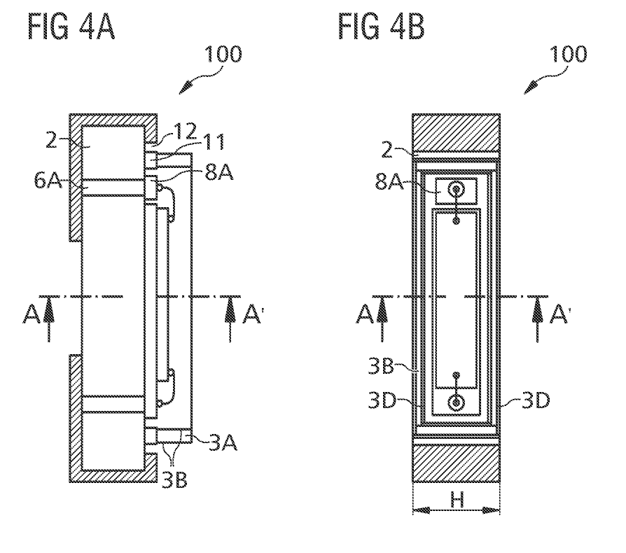

FIG. 4A and 4B a third exemplary embodiment of an optoelectronic semiconductor component in a schematic top view (FIG. 4A) and side view (FIG. 4B),

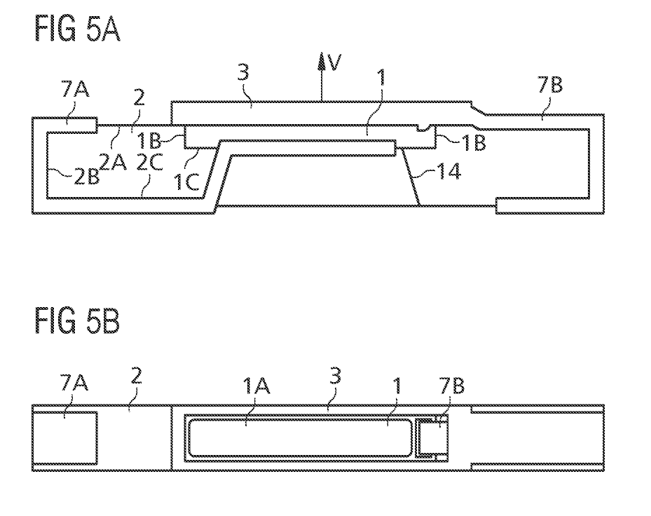

FIG. 5A and 5B a fourth exemplary embodiment of an optoelectronic semiconductor component in a schematic top view (FIG. 5A) and side view (FIG. 5B),

FIG. 1A, 1B and 1C illustrate a possible arrangement with an optoelectronic semiconductor component 100 described here. The semiconductor component 100 is in particular a radiation-emitting semiconductor component, which is configured as a side emitter. The optoelectronic semiconductor component 100 comprises an optoelectronic semiconductor chip 1 and a carrier element 2, on which the semiconductor chip 1 is arranged. The semiconductor component 100 further comprises a reflector body 3 with a cavity 3C in which the semiconductor chip 1 is arranged.

The semiconductor component 100 is arranged on a connection carrier 16 by means of its assembly surface 4. The connection carrier 16 is in particular a circuit board. A connecting means 15, in particular a solder, is located between the optoelectronic semiconductor component 100 and the connection carrier 16 for fixing the semiconductor component 100 to the connection carrier 16. As illustrated in FIG. 1B, the fixing means 15 can be arranged along the assembly surface 4 from the edges. In particular, the fixing means 15 is arranged on a first main surface 2A, two opposite side surfaces 2B and a second main surface 2C of the carrier element 2. In particular, contact layers (not illustrated) arranged on the carrier element 2 are mechanically and electrically conductively connected to the connection carrier 16 by means of the connecting means 15. Said connecting means can also be arranged between the assembly surface 4 and the connection carrier 16 (see FIG. 1C for comparison).

The optoelectronic semiconductor component 100 can have an enclosure 5 in which the semiconductor chip 1 is embedded. A conversion element can be formed by means the enclosure 5. Said enclosure preferably extends to external surfaces 3D of the reflector body 3.

The reflector body 3 allows a majority of the impinging radiation to be reflected in a preferred direction V, and therefore the semiconductor component 100 emits a majority of the radiation in the preferred direction V. In particular, said preferred direction V runs perpendicular to the first main surface 2A and parallel to the connection carrier 16.

The optoelectronic semiconductor component 100 can be designed in comparatively flat manner and is thus particularly suitable for forming a flat background lighting arrangement, which can be used for a display, for example. In particular, the reflector body 3 has a height L of between 20 μm and 200 μm and a wall thickness S of between 10 μm and 100 μm, in particular between 30 μm and 50 μm. Furthermore, the optoelectronic semiconductor component 100 in particular has a component height H of between 0.15 mm and 0.4 mm.

FIG. 2A and 2B show a first exemplary embodiment of an optoelectronic semiconductor component 100, which is suitable as a side emitter.

In this embodiment, the carrier element 2 is designed in an even manner. Said carrier element 2 comprises in particular a silicon or ceramic substrate. By using a silicon or ceramic substrate, the carrier element 2 simultaneously forms a good heat sink.

A first through connection 6A and a second through connection 6B are arranged in the carrier element 2. The first and second through connections 6A, 6B extend through the carrier element 2 and extend from the first main surface 2A to the second main surface 2C.

Furthermore, a first contact layer 7A and a second contact layer 7B are arranged on the carrier element 2, said contact layers being provided for electrically connecting the optoelectronic semiconductor chip 1. The first contact layer 7A and the second contact layer 7B each extend from the first main surface 2A via a side surface 2B to the second main surface 2C.

Furthermore, a first and second connecting surface 8A, 8B are arranged on the first main surface 2A of the carrier element 2. The first through connection 6A connects the first connecting surface 8A with the first contact layer 7A. The second through connection 6B connects the second connecting surface 8B with the second contact layer 7B. In particular, the through connections 6A, 6B are covered by the connecting surfaces 8A, 8B. For example, a connecting surface 8A, 8B can be 300 μm×300 μm in size. The optoelectronic semiconductor chip 1 is attached on the second connecting surface 8B.

The optoelectronic semiconductor chip 1 has a first electric contact 9A and a second electric contact 9B, wherein the first electric contact 9A is connected with the first connecting surface 8A and the second electric contact 9B is connected to the second connecting surface 8B. For example, the first contact 9A can be arranged on a front side surface 1A of the semiconductor chip 1. Furthermore, the second contact 9B can be provided on a substrate of the semiconductor chip 1. Both electric contacts 9A, 9B are each connected to the connecting surfaces 8A, 8B by means of an electric conductor 10, in particular of a bond wire.

The contact layers 7A, 7B, the through connections 6A, 6B and the connecting surfaces 8A, 8B are preferably produced from a single coating, which is applied to the carrier element 2. Said carrier element 2 can initially be provided with recesses by means of photo structuring, which are subsequently filled in when coating the carrier element 2 with coating material, wherein the through connections 6A, 6B are created. For example, the coating material can be composed of copper. The coating can be applied to the carrier element 2 with a thickness of 1 μm to 50 μm. The through connections 6A, 6B can be configured with a diameter of 100

The optoelectronic semiconductor component 100 further comprises a reflector body 3, which is arranged on the first main surface 2A of the carrier element 2. As can be discerned from FIG. 2A and 2B, the reflector body 3 can be arranged on a contact frame 11, which in particular is produced from the same coating as the contact layers 7A, 7B and connecting surfaces 8A, 8B. The contact frame 11 is separated from the contact layers 7A, 7B and connecting surfaces 8A, 8B by intermediate spaces 12, which contain no coating material. The contact frame 11 is electrically insulated from the contact layers 7A, 7B and connecting surfaces 8A, 8B by the electrically insulating carrier element 2, and therefore the reflector body 3, which is also attached on the contact frame 11, is also electrically insulated.

For producing the reflector body 3, a photoresist can be applied to the carrier element 2 and structured in such a way that a cavity is created, which is limited by a reflector base body composed of photoresist. The reflector element can be galvanically grown in the cavity. The reflector element is preferably galvanically grown on the contact frame 11. In particular, nickel and/or copper are used as base material for the galvanic growth. In addition, the base material can be overlaid with a further material, such as aluminium, silver or gold, for improving the reflectivity. The reflector base body composed of photoresist is removed after production of the reflector element. The reflector body 3 thus consists of the reflector element 3B, wherein said reflector element 3B consists of a metal, a metal compound or a metal sequence.

The reflector element 3B is configured in a self-supporting manner and is inseparably connected to the carrier element 2 with no additional fixing means.

Furthermore, the reflector element 3B is configured in a frame-like manner and limits a cavity 3C on the inside, the optoelectronic semiconductor chip 1 being arranged in said cavity. In particular, the reflector element 3B comprises a plurality of side walls 3D, which are arranged parallel to side surfaces 1B of the semiconductor chip 1.

The reflector element 3B allows the intensity of the radiation emitted in the preferred direction to be advantageously increased.

In the first embodiment the contact layers 7A, 7B are arranged outside the cavity 3C of the reflector element 3B and separated therefrom by the intermediate space 12. However, in order to avoid having to guide the electric conductor 10 via the reflector element 3B to the contact layers 7A, 7B, the connecting surfaces 8A, 8B are provided in the cavity 3C, said connecting surfaces 8A, 8B being electrically connected with the contact layers 7A, 7B by means of the through connections 6A, 6B. In the second exemplary embodiment of an optoelectronic semiconductor component 100 illustrated in FIG. 3A and 3B, the carrier element 2 is configured in an even manner. The carrier element 2 comprises a plastic carrier. Suitable materials for the plastic carrier are FR4, epoxy or polyimide, for example. Such materials are cost-effective circuit board materials. The carrier element 2 has no through connections, as the latter cannot be configured as small as they would need to be in such a carrier element 2. The contact layers 7A, 7B thus extend into the cavity 3C of the reflector body 3. However, in order to electrically insulate the reflector body 3 from the contact layers 7A, 7B, an insulating layer 13 is arranged between the reflector body 3 and the first and second contact layer 7A, 7B, said insulating layer 13 containing a dielectric material. Suitable materials for the insulating layer 13 are polymers, such as polyimide, epoxide, acrylate or silicon, for example. The insulating layer 13 is configured in a frame-like manner. The reflector body 3, which is arranged on the insulating layer 13, is also configured in a frame-like manner. As in the first exemplary embodiment, the reflector body 3 according to the second exemplary embodiment also preferably consists of only the reflector element 3B and is in particular galvanically grown on the insulating layer 13. That is, the reflector body 3 has no reflector base body 3.

In FIG. 4A and 4B is illustrated a third exemplary embodiment of an optoelectronic semiconductor component 100 which, unlike the first and second embodiments, has a reflector body with a reflector base body 3A and a reflector element 3B. In particular, the reflector base body 3A contains a dielectric material. The reflector base body 3A can be made of an organic material, such as a plastic, for example. It is conceivable that the reflector base body 3A could be configured by means of a moulding process, such as injection moulding or injection pressing, directly on the carrier element 2, and then moulded onto the latter. This has the advantage that no adhesion promotor is needed. Furthermore, it is conceivable that the reflector base body 3A could be produced as individual component or separately as a composite, for example by means of a moulding process and attached on the carrier element 2. A photo-structurable dielectric is also a possibility for producing the reflector base body 3A. High aspect ratios can be achieved by means of a moulding process, which is in particular implemented by a LIGA (German acronym for lithography, galvanic processes and moulding) process, or a photo-structuring. The reflector element 3B can be produced by means a metallic coating of the reflector base body 3A. For example, the coating can be produced by means of electroless galvanic processes or by isotropic sputtering. A suitable material for the reflector element 3B is in particular silver. In particular, the reflector element 3B covers all free surfaces of the reflector base body 3A, i.e. all surfaces not covered by another element, such as the contact frame 11.

Other than the reflector body, the optoelectronic semiconductor component 100 according to the third exemplary embodiment can be configured in the same way as the optoelectronic semiconductor component 100 according to the first exemplary embodiment or even the second exemplary embodiment regarding construction and component parts. The carrier element 2 in the fourth embodiment of an optoelectronic semiconductor component 100 shown in FIG. 5A and 5B is a shaped body in which the optoelectronic semiconductor chip 1 is partially embedded. The carrier element 2 is thereby configured in an uneven manner.

The shaped body can be formed of a moulding composition, which contains a plastic material, for example a duroplastic material, such as epoxide or silicon. For example, the moulding composition can be applied to the semiconductor chip 1 by means of injection or moulding. The application of the moulding composition preferably ensues in a so-called transfer moulding process, for instance a film transfer moulding process or a so-called compression moulding process.

The shaped body in particular completely covers two side surfaces 1B of the semiconductor chip 1. Furthermore, a rear surface 1C of the semiconductor chip 1 facing the carrier element 2 is partially covered by the shaped body. Conversely, the front surface 1A opposite to the rear surface 1C is preferably uncovered by the shaped body.

The first contact layer 7A extends from the first main surface 2A via a side surface 2B and the second main surface 2C of the carrier element 2 to an opening 14 of the carrier element 2 and ends on the rear surface 1C of the semiconductor chip 1. In particular, the first contact layer 7A is connected with the first electric contact (not illustrated) of the semiconductor chip 1. The opening 14 can be filled with the moulding composition after production of the contact layers 7A, 7B.

Furthermore, the second contact layer 7B extends to the lateral front surface 1A of the semiconductor chip 1. The second contact layer 7B can be in direct contact with the reflector body 3. However, the reflector body 3 is spaced from the first contact layer 7A and electrically insulated from the first contact layer 7A by the carrier element 2, and therefore no short circuit between the two contact layers 7A, 7B is to be feared due to the reflector body 3. Said reflector body 3 can consist of the reflector element according to the first and second exemplary embodiment or of a reflector base body and a reflector element according to the third embodiment.

The present application claims the priority of the German application DE 10 2013 114 345.8, the disclosure content of which is hereby incorporated by reference.

The invention is not limited by the description by means of the exemplary embodiments. Rather, the invention encompasses every new feature as well as every combination of features, which particularly includes every combination of features in the claims, even if such feature or such combination is not explicitly stated in the claims or exemplary embodiments.

1. Optoelectronic semiconductor component with
an optoelectronic semiconductor chip,
a carrier element, having a first main surface a second main surface opposite to the first main surface and a plurality of side surfaces connecting the first and second main surfaces, wherein the optoelectronic semiconductor chip is arranged on the side of the first main surface on the carrier element,
an assembly surface, which is provided for assembling the semiconductor component and is, in particular, arranged parallel to a side surface of the carrier element,
a reflector body, which is arranged on the carrier element, comprising a cavity in which the optoelectronic semiconductor chip is arranged and comprising a reflector element, which limits the cavity and consists of a metal, a metal compound or a metal sequence.

2. Optoelectronic semiconductor component according to claim 1, wherein
the reflector body consists of the reflector element,
the reflector element is connected with the carrier element-424 without additional fixing means.

3. Optoelectronic semiconductor component according to he claim 1,
wherein the reflector element and/or the reflector body is inseparably connected with the carrier element.

4. Optoelectronic semiconductor component according to claim 1,
wherein the reflector body consists of the reflector element.

5. Optoelectronic semiconductor component according to claim 1,
wherein the reflector body comprises a reflector base body, on which the reflector element is attached.

6. Optoelectronic semiconductor component according to claim 1,
wherein the reflector base body contains a dielectric material.

7. Optoelectronic semiconductor component according to claim 1,
wherein the reflector element contains nickel.

8. Optoelectronic semiconductor component according to claim 1,
wherein the reflector body has a wall thickness (S) of between 30 μm and 50 μm.

9. Optoelectronic semiconductor component according to claim 1,
having an enclosure, which is arranged on an external surface of the reflector body.

10. Optoelectronic semiconductor component according to claim 1,
wherein the enclosure is arranged in the cavity and covers the optoelectronic semiconductor chip.

11. Optoelectronic semiconductor component according to claim 1,
having a first contact layer and a second contact layer, which are arranged on the carrier element and are provided for electrically connecting the optoelectronic semiconductor chip, wherein the first contact layer and the second contact layer each extend from the first main surface via a side surface to the second main surface.

12. Optoelectronic semiconductor component according to claim 1,
wherein the reflector body is electrically insulated from at least one of the two contact layers.

13. Optoelectronic semiconductor component according to claim 1,
wherein an insulating layer is arranged between the reflector body and the first and second contact layer, and wherein said insulating layer contains a dielectric material.

14. Optoelectronic semiconductor component according to claim 1,
wherein a first and a second through connection are arranged in the carrier element, and wherein said through connections in each case extend from the second main surface to the second main surface of the carrier element, wherein the first through connection is electrically connected with the first contact layer and the second through connection is electrically connected with the second contact layer.

15. Optoelectronic semiconductor component according to claim 1,
wherein the carrier element comprises a silicon substrate, a ceramic substrate or a plastic carrier.

16. Optoelectronic semiconductor component according to claim 1,
wherein the carrier element is a shaped body into which the optoelectronic semiconductor chip is partially embedded.

17. Method for producing an optoelectronic semiconductor component according to claim 1 with the following steps:
providing a carrier element
providing a reflector base body on the carrier element,
producing a reflector element composed of a metal or a metal compound in such a way that the reflector element is in direct contact with the reflector base body.

18. Method according to claim 1, wherein the reflector element is galvanically grown.

19. Method according to claim 17, wherein the reflector base body is removed from the carrier element after production of the reflector element.

20. Optoelectronic semiconductor component with
an optoelectronic semiconductor chip,
a carrier element, having a first main surface, a second main surface opposite to the first main surface and a plurality of side surfaces connecting the first and second main surfaces, wherein the optoelectronic semiconductor chip is arranged on the side of the first main surface on the carrier element,
an assembly surface, which is provided for assembling the semiconductor component and is arranged parallel to a side surface of the carrier element,
a reflector body, which is arranged on the carrier element, comprising a cavity in which the optoelectronic semiconductor chip is arranged and consisting of a reflector element, which limits the cavity and consists of a metal, a metal compound or a metal sequence, wherein said reflector element has a height of between 20 μm and 200 μm.
